(19) United States
(12) Patent Application Publication
(10) Pub. No.: US 2024/0172402 A1
(43) Pub. Date: May 23, 2024

(54) COOLING SYSTEM WITH IN-SERIES HIGH-TEMPERATURE AND LOW-TEMPERATURE CIRCUITS

(71) Applicant: THERMAL WORKS LLC, Darien, CT (US)

(72) Inventors: Doron Shapiro, St. Louis, MO (US); Paul Tarangelo, Lagrangeville, NY (US)

(73) Assignee: THERMAL WORKS LLC, Darien, CT (US)

(21) Appl. No.: 18/514,953

(22) Filed: Nov. 20, 2023

Related U.S. Application Data
(60) Provisional application No. 63/427,515, filed on Nov. 23, 2022.

(51) Int. Cl. H05K 7/20

(52) U.S. Cl. CPC H05K 7/20836; H05K 7/20309; H05K 7/20318; H05K 7/20327; H05K 7/20354

(57) ABSTRACT

A cooling system and method of controlling are disclosed. The cooling system includes a high-temperature circuit with a relatively high temperature evaporator and a relatively low temperature circuit with a low temperature evaporator. The cooling system enables a glycol-water solution to flow through the high-temperature circuit and the low-temperature circuit in series. The method of controlling provides an ability to operate the cooling system in a full free cooling mode using no compressors, a partial free cooling mode using one or more compressors, and in a mechanical cooling mode using one or more compressors.

### FIELD

The present disclosure relates generally to chilling and cooling systems and more particularly to cooling systems including series-connected high-temperature and low-temperature circuits and to methods and systems for controlling cooling systems.

### BACKGROUND

In recent years, with the exponential growth of computational technologies, such as artificial intelligence (AI), machine learning, big data analytics, and high-performance computing, data centers have rapidly expanded in size and complexity. Such data centers house a vast array of servers, storage devices, networking equipment, and other essential infrastructure components, all of which are dedicated to processing, transmitting, and storing an ever-growing volume of digital information. As data centers scale up to meet these demands, data centers inherently accommodate a higher density of computing hardware, resulting in an increase in the overall power consumption and, consequently, heat generation.

Computing systems, which form the core of these data centers, inherently produce heat as a byproduct of their operation. Such heat generation is due to the resistance encountered by electric currents as they flow through the electronic components, such as processors, memory modules, and other integrated circuits. When such components are subjected to heavy computational tasks, as is common in AI and other advanced applications, they draw more power and, in turn, dissipate more heat.

Effective cooling of computing systems in data centers and in other applications is paramount for several reasons. Firstly, elevated temperatures can significantly degrade the performance of computing systems. As temperatures rise, processors and other components may throttle their performance to avoid overheating, leading to reduced computational throughput.

Additionally, prolonged exposure to high temperatures can lead to accelerated wear and tear, reducing the lifespan of these components. In extreme cases, overheating can result in physical damage to the hardware or even pose a fire risk. Furthermore, excessive heat can negatively impact the reliability of a data center, leading to potential downtimes and disruptions in critical services. Thus, in the realm of burgeoning data center infrastructure, there is an ongoing need for innovative cooling solutions that can effectively manage heat, ensuring optimum performance, reliability, and longevity of the underlying computing systems.

### SUMMARY

In the ever-evolving landscape of data center infrastructure, space conservation is a paramount concern. Data centers are under increasing pressure to maximize the utility of every square foot of their facilities. The optimization of space is not merely a matter of cost but is essential for operational efficiency, scalability, and future expansion.

Conventional cooling systems pose challenges for space conservation. Such systems typically consist of an array of separate components, ranging from chillers to fluid coolers. Each of these components necessitates a significant amount of space. Beyond their inherent dimensions, these components often require additional service clearances to facilitate maintenance, repairs, and replacements as well as space required for connecting the components.

Conventionally, operators of data centers must obtain a number of separate units such as heat exchangers, chillers, pumps, etc., and hire an expert control systems engineer to integrate each of the separate units into the building to create the cooling system. Next, the necessary cooling in terms of tonnage must be calculated and the chillers may be staged up or staged down depending on the calculated tonnage. Such a piecemeal approach has resulted in complex cooling systems requiring many parts and without the ability to be controlled in a precise and efficient manner.

The integration of these components necessitates piping to transport electric lines, cooling fluids, and/or air between different parts of the system. The space required for this piping is compounded by the need for insulation, support structures, and safe access pathways for maintenance personnel. Moreover, the complex web of piping can restrict airflow, creating further inefficiencies and challenges in temperature regulation.

While conventional cooling mechanisms are vital for ensuring the functionality and longevity of computing systems within a data center, they inherently consume significant real estate. This consumption can constrain the available space for other critical infrastructure, impede the data center's growth, and introduce operational inefficiencies.

Economic efficiency is pivotal for the sustainable and competitive operation of data centers in today's business environment. As the demand for data processing capabilities grows, so does the pressure on data center operators to provide services at scale, without exponentially increasing operational costs. A significant portion of costs of operating a data center is attributed to cooling infrastructure, which is essential for maintaining the longevity and optimal performance of the data center's computational hardware.

Conventional cooling systems come with high capital and operational costs. The initial investment in procuring such systems can be substantial, given the intricate machinery and specialized components they comprise. Moreover, the installation of such systems can be labor-intensive and time-consuming, necessitating specialized skills, extensive planning, and structural modifications to the data center facility. These installation complexities not only escalate costs but can also lead to prolonged downtimes, affecting the data center's service delivery and profitability. Furthermore, the operational costs associated with conventional cooling solutions can be incessant. Operational costs encompass regular maintenance of individual components, part replacements, and energy expenses related to running these systems continuously.

Conventional cooling systems are also unable to perform effective load matching stemming from the use of mismatched components. As the cooling demand fluctuates based on computational activity and external environmental factors, conventional cooling systems struggle to adjust cooling output precisely according to the real-time needs of the data center.

Conventional cooling setups exhibit a low temperature differential, or delta. A low delta signifies only a modest temperature difference, e.g., 10 to 20 degrees Fahrenheit, between the coolant's supply and return lines. While such a system might have been satisfactory for less demanding setups, modern data centers generate heat at an unprecedented scale. An inadequate delta can, thus, hinder the efficient removal of this excess heat, potentially jeopardizing the performance and longevity of the servers. The challenges of mismatched components leading to poor load matching, combined with a low delta, highlight the urgent need for innovative cooling solutions tailored to the unique requirements of modern data centers.

There remains a need for an efficient and cost-effective cooling system capable of being installed as a single unit with a minimal number of components and capable of being automatically and precisely controlled to provide efficient cooling.

As described herein, a cooling solution may be achieved which enhances performance while drastically reducing the spatial footprint of conventional cooling systems for use in a modern data center environment. A cooling system as described herein is cost-effective, utilizes a simplified control system, and efficiently addresses the cooling demands of modern data centers.

For example, a cooling system as described herein may provide a delta of up to 40 degrees Fahrenheit.

With high-delta cooling, chillers piped in series are typically more efficient due to the lower temperature lift seen by the first chiller, and allow for better load matching and improved part-load performance. When chillers are piped in series, they work together to meet the cooling demand, and each chiller can operate at a higher part-load efficiency. This configuration is particularly advantageous when the cooling load varies throughout the day or season because it enables the chillers to modulate their capacity to match the load more precisely. Additionally, piping chillers in series can lead to energy savings and reduced operating costs compared to a parallel configuration, where each chiller operates independently at part load.

The above-discussed needs and other needs are addressed by the present disclosure of a cooling system including series-connected high-temperature and low-temperature circuits. A cooling system according to one or more of the embodiments described herein may comprise few components as compared to conventional cooling systems while providing cooling in a more efficient and compact manner. In one or more of the embodiments described herein, a cooling system is a high-delta system capable of providing efficient cooling while being controlled automatically based on real-time feedback from sensors throughout the cooling system.

A cooling system as described herein may comprise a flow of a solution of water and/or glycol controlled by an integrated variable speed pump through a series of heat exchangers. The glycol solution described herein may comprise a ratio of propylene glycol to water. In some embodiments, a ratio of 30-70 of premixed propylene glycol-to-water may be used, though it should be appreciated any ratio from 0-100 to 100-0 glycol-to-water may be used. Further, other common heat transfer fluids such as ethylene glycol/water or silicone-based heat transfer fluids may be used.

Conventionally, when an operator of a building, such as a data center, seeks to install a cooling system, the operator must obtain a number of separate units such as heat exchangers, chillers, pumps, etc., and must hire an expert to integrate each of the separate units into the building to create the cooling system. Next, the necessary cooling in terms of tonnage must be calculated and the chillers may be staged up or staged down depending on the calculated tonnage. Such a piecemeal approach has resulted in complex cooling systems requiring many parts and without the ability to be controlled in a precise and efficient manner.

Using a cooling system as described herein, on the other hand, a blended system is enabled. An entire cooling system may be provided as a single unit. By providing the entire cooling system as a single unit, more complex control schemes may be provided as compared to conventional systems as described herein according to one or more embodiments. For example, based on information provided by a number of sensors, information such as glycol/water flowrate, temperature, pressure, etc., may be used to select proper functioning of features such as fans, condensers, evaporators, etc., as described herein in such a manner as to minimize overall power use.

In one or more of the embodiments described herein, a cooling system may comprise at least two refrigerant circuits. A first refrigerant circuit may comprise a first evaporator and a second refrigerant circuit may comprise a second evaporator. The first refrigerant circuit may be configured to act as a high-temperature (HT) circuit and the second refrigerant circuit may be configured to act as a low-temperature (LT) circuit. The evaporator of the HT circuit may be configured to operate at a higher temperature as compared to the evaporator of the LT circuit. For example, the higher evaporating temperature may be approximately 70 to 80° F. and the lower evaporating temperature may be approximately 55 to 65° F. The evaporators described herein may be flooded evaporators in which a pool of refrigerant in a shell submerges tubes through which the glycol solution flows.

In a cooling system as described herein, a glycol-water solution flows from a piping system through first the HT circuit and then the LT circuit in series before being used to cool a location such as a data center and finally returning to the piping system. The HT and LT circuits may be controlled to operate in a variety of modes such as a free-cooling or full-economizer mode, a partial free-cooling or economizer with mechanical assist mode, and a mechanical or full mechanical cooling mode. Each mode is described in greater detail below. Switching between the modes may be performed automatically and may involve turning off and on or adjusting various valves, pumps, heat exchangers, compressors, condensers, fans, etc.

The above-described embodiments and configurations are neither complete nor exhaustive. As will be appreciated, other embodiments of the disclosure are possible utilizing, alone or in combination, one or more of the features set forth above or described in detail below.

The following definitions are used herein:

The phrases “at least one,” “one or more,” “or,” and “and/or” are open-ended expressions that are both conjunctive and disjunctive in operation. For example, each of the expressions “at least one of A, B, and C,” “at least one of A, B, or C.” “one or more of A, B, and C.” “one or more of A, B, or C.” “A, B, and/or C,” and “A, B, or C” means A alone, B alone, C alone, A and B together, A and C together, B and C together, or A, B, and C together.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

The term “automatic” and variations thereof, as used herein, refers to any process or operation, which is typically continuous or semi-continuous, done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

Aspects of the present disclosure may take the form of an embodiment that is entirely hardware, an embodiment that is entirely software (including firmware, resident software, micro-code, etc.) or an embodiment combining software and hardware aspects that may all generally be referred to herein as a “circuit,” “module,” or “system.” Any combination of one or more computer-readable medium(s) may be utilized. The computer-readable medium may be a computer-readable signal medium or a computer-readable storage medium.

A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer-readable storage medium may be any tangible, non-transitory medium that can contain or store a program for use by or in connection with an instruction execution system, apparatus, or device.

A computer-readable signal medium may include a propagated data signal with computer-readable program code embodied therein, for example, in baseband or as part of a carrier wave. Such a propagated signal may take any of a variety of forms, including, but not limited to, electro-magnetic, optical, or any suitable combination thereof. A computer-readable signal medium may be any computer-readable medium that is not a computer-readable storage medium and that can communicate, propagate, or transport a program for use by or in connection with an instruction execution system, apparatus, or device. Program code embodied on a computer-readable medium may be transmitted using any appropriate medium, including, but not limited to, wireless, wireline, optical fiber cable, RF, etc., or any suitable combination of the foregoing.

The terms “determine,” “calculate,” “compute,” and variations thereof, as used herein, are used interchangeably, and include any type of methodology, process, mathematical operation, or technique.

The term “means” as used herein shall be given its broadest possible interpretation in accordance with 35 U.S.C., Section 112(f) and/or Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary, brief description of the drawings, detailed description, abstract, and claims themselves.

The preceding is a simplified summary of the invention to provide an understanding of some aspects of the invention. This summary is neither an extensive nor exhaustive overview of the invention and its various embodiments. It is intended neither to identify key or critical elements of the invention nor to delineate the scope of the invention but to present selected concepts of the invention in a simplified form as an introduction to the more detailed description presented below. As will be appreciated, other embodiments of the invention are possible utilizing, alone or in combination, one or more of the features set forth above or described in detail below. Also, while the disclosure is presented in terms of exemplary embodiments, it should be appreciated that an individual aspect of the disclosure can be separately claimed.

### BRIEF DESCRIPTION OF THE DRAWINGS

The present disclosure may take form in various components and arrangements of components, and in various steps and arrangements of steps. The drawings are only for purposes of illustrating the preferred embodiments and are not to be construed as limiting the disclosure. In the drawings, like reference numerals refer to like or analogous components throughout the several views.

FIG. 1 is a schematic of a cooling system in accordance with one or more of the embodiments described herein;

FIG. 2 is an illustration of a cooling system in accordance with one or more of the embodiments described herein;

FIG. 3A is an illustration of a front view of a cooling system in accordance with one or more of the embodiments described herein;

FIG. 3B is an illustration of a rear view of a cooling system in accordance with one or more of the embodiments described herein;

FIG. 4 is an illustration of a fan unit of a cooling system in accordance with one or more of the embodiments described herein;

FIG. 5 is a flowchart of a method in accordance with one or more of the embodiments described herein;

FIG. 6 is a block diagram of features of a cooling system in accordance with one or more of the embodiments described herein; and

FIG. 7 is a block diagram of a controllable cooling system in accordance with one or more of the embodiments described herein.

### DETAILED DESCRIPTION

The ensuing description provides embodiments only and is not intended to limit the scope, applicability, or configuration of the claims. Rather, the ensuing description will provide those skilled in the art with an enabling description for implementing the embodiments. It will be understood that various changes may be made in the function and arrangement of elements without departing from the spirit and scope of the appended claims.

Any reference in the description comprising an element number, without a sub element identifier when a sub element identifier exists in the figures, when used in the plural, is intended to reference any two or more elements with a like element number. When such a reference is made in the singular form, it is intended to reference one of the elements with the like element number without limitation to a specific one of the elements. Any explicit usage herein to the contrary or providing further qualification or identification shall take precedence.

The exemplary systems and methods of this disclosure will also be described in relation to analysis software, modules, and associated hardware. However, to avoid unnecessarily obscuring the present disclosure, the following description omits well-known structures, components, and devices, which may be omitted from or shown in a simplified form in the figures or otherwise summarized.

For purposes of explanation, numerous details are set forth in order to provide a thorough understanding of the present disclosure. It should be appreciated, however, that the present disclosure may be practiced in a variety of ways beyond the specific details set forth herein.

Benefits provided by a cooling system as described herein include reduced power requirements per unit of cooling (kW per ton) as compared to conventional systems. Also, a cooling system as described herein may be installed as a single component as opposed to conventional systems which require multiple components (such as pumps, condensers, fans, etc.) located in multiple locations (e.g., indoors and outdoors). Furthermore, a cooling system as described herein comprises chilled water or glycol solution circuits connected in series as opposed to parallel. By having two chilled water circuits, each with an evaporator operating at a different evaporating temperature, a great efficiency boost is achieved as compared to conventional systems.

A cooling system as described herein may provide, for example, a megawatt of chilling. To achieve a similar performance with a conventional cooling system may require additional heat exchangers and other components due to non-continuous step changes in components such as compressors performance. As a result, a cooling system in accordance with embodiments described herein results in lesser costs for equipment, reduced maintenance, and greater energy efficiency.

A cooling system as described herein provides a high-delta system (i.e., the temperature difference between the water supply to the chiller and the water returning to the chiller to be chilled is relatively high as compared to low-delta systems). By offering a high-delta system, efficiency improvements are achieved, pipe sizes can be reduced because less mass flow through the piping is required, and other benefits are achieved, as compared to conventional low-delta systems. As described herein, a cooling system may be enabled to accept input water of, for example, 97 degree Fahrenheit water entering and output 62 degree Fahrenheit water leaving the cooling system.

The glycol solution returns from the data center (or other environment to be cooled) and flows first through one or more free cooling coils (i.e., fluid coolers) which are in a series flow arrangement with a first evaporator and a second evaporator. These two evaporators in series achieve greater cooling efficiencies as compared to conventional systems.

Fluid cooler heat exchangers as described herein may be used to cool the glycol solution using ambient air in one or more of the operating modes described below. Using condenser heat exchangers, a refrigerant may be condensed by ambient air.

The cooling system may in one or more embodiments comprise, for example, one or more fluid cooler heat exchangers, condenser heat exchangers, refrigerant receivers, one or more variable speed fans, a variable speed pump, at least two compressors comprising compressor circuits, which may be used to cool the glycol solution on warmer days, at least two evaporators in which refrigerant may be used to cool the glycol solution flowing through the evaporators when the compressors are running, at least two electronic expansion valves which may be used to regulate the flow of refrigerant through the evaporators, one or more three-way valves which may be used to control the glycol solution flow through the fluid cooler plus evaporators or divert flow through the evaporators only, one or more control panels and electrical power panels which may house the PLC-based controls and power distribution equipment, and an automatic transfer switch with a built-in power meter, among other components. In contrast to conventional systems, water for evaporative cooling is not required using a cooling system as described herein, resulting in reduced cost and improved performance, and less maintenance.

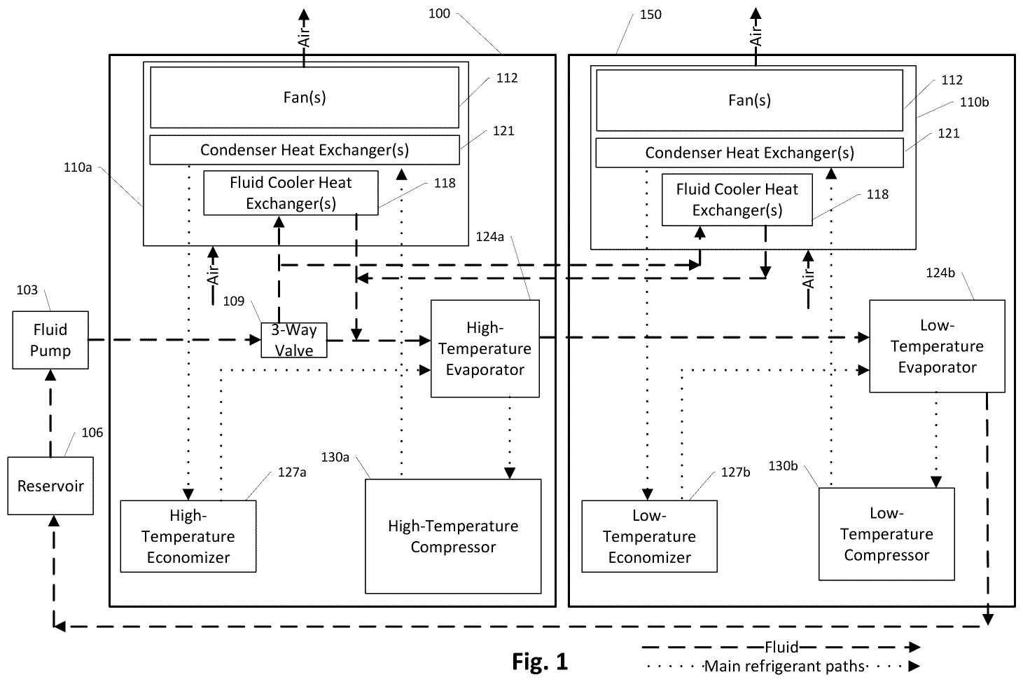

A cooling system as described herein may comprise a fluid pump 103, a high-temperature (HT) circuit 100, and a low-temperature (LT) circuit 150 as illustrated in FIG. 1. The HT circuit 100 may enable a flow of fluid (which may be referred to as a solution), such as a glycol-water solution, to the LT circuit 150 such that the solution flows in series through the HT circuit and the LT circuit. The dashed arrow lines in FIG. 1 represents fluid, the dotted arrow lines in FIG. 1 represent a flow of refrigerant, and the fans 112 may be used to exhaust air as illustrated by the arrows labeled “air.”

The flow of a glycol-water solution through the cooling system may begin in the HT circuit 100 with a pump 103 drawing the solution from a reservoir 106 or direct from a data center or other location being cooled. One or more three-way valves 109 may control the flow of the solution to one or more condenser fans 112a, 112b.

A three-way valve 109 may control the flow of solution between a mechanical cooling mode, in which 100% of the solution from the pump 103 enters an HT flooded evaporator 124a, and a free cooling mode, in which the solution flows from pump 103 into the fluid cooler heat exchanger 118 before entering at least two flooded evaporators 124a and 124b, which may be inactive in said free-cooling mode. Further, it should be appreciated any ratio of free-cooling versus mechanical cooling can exist in a partial free cooling mode by first cooling the solution in the fluid cooler heat exchangers(s) 118 followed by the evaporators 124a, 124b. In this way, each of a free-cooling mode, a partial free-cooling mode, and a mechanical cooling mode can be achieved as described herein.

The cooling system may include one or more fan units 112. In some implementations, each of the HT circuit 100 and the LT circuit 150 may be associated with one or more particular fan units 112. Air may enter fan units 112 by first passing through one or more fluid cooler heat exchangers 118 followed by one or more condenser heat exchangers 121, before being exhausted from one or more condenser fans 112. One or more condenser fans 112 may be referred to as HT fans as such fans may be associated with air used in the HT circuit 100 while other condenser fans 112 may be referred to as LT fans as such fans may be associated with air used in the LT circuit 150.

The HT circuit 100 of the cooling system may comprise one or more HT heat exchanger evaporators 124a and economizers 127a, where the economizer(s) 127a pre-cool liquid refrigerant upstream of the evaporator(s) 124a. Refrigerant flowing from the condenser 121 may reach the HT economizer 127a and may be passed into the HT evaporator 124a to be used to cool the glycol solution.

The evaporator 124a (which may be a flooded evaporator for example) may be configured to emit the glycol solution from the HT circuit 100 to an LT evaporator 124b of an LT circuit 150 of the cooling system.

Glycol solution may enter the LT circuit 150 from the HT evaporator 124a of the HT circuit 100 and into an evaporator 124b (which may be a flooded evaporator for example) of the LT circuit 150. The evaporator 124b of the LT circuit 150 may be associated with a lesser evaporating temperature as compared to the evaporator 124a of the HT circuit 100.

The flooded evaporator 130 of the LT circuit may also receive refrigerant from a low-temperature economizer 127b.

It should be appreciated that each of the HT circuit 100 and the LT circuit 150 may further comprise one or more load-balancing valves, staging valves, economizer expansion valves, and/or other valves. Such valves may controllable and be used to control the flow of refrigerant, fluid, air, etc., through each of the HT circuit 100 and the LT circuit 150.

After passing through the evaporator 124b of the LT circuit 150, the glycol solution may be emitted to one or more building units that require cooling.

Throughout the cooling system, any number of temperature sensors, pressure sensors, and/or other sensors may be installed to monitor the temperature, flow rate, and other variables associated with the cooling system. Load of the cooling system may be calculated based on flow rate and temperature of the glycol solution.

Modes of Use

As described herein, a cooling system, such as that illustrated in FIG. 1, may be capable of operating in a full free cooling mode using no compressor circuits, a partial-free cooling mode using one or more compressor circuits, or a mechanical cooling mode with one or more compressor circuits.

In a free cooling mode, the fluid (e.g., glycol/water solution) may be cooled by ambient air using coils of fluid cooler heat exchangers 118 in one or more of the HT circuit 100 and the LT circuit 150 while compressors 130a, 130b in the HT circuit 100 and the LT circuit 150 are turned off. Thus in free cooling mode, the HT evaporator 124a and the LT evaporator 124b may not be used to provide cooling. The glycol solution may return to a glycol supply reservoir 106.

In a partial free cooling mode, the fluid (e.g., glycol/water solution) may be partially cooled by ambient air and partially by one or more compressors 130a, 130b. As illustrated in FIG. 1, the fluid may pass through coils of both HT fluid cooler heat exchanger(s) and LT fluid cooler heat exchanger(s) 118 while one or both of the HT compressor 130a and the LT compressor 130b are active. The fluid may first pass through coils of the fluid cooler heat exchanger(s) 118 in the HT circuit 100 and the LT circuit 150 in parallel where the fluid may be partially cooled by ambient air, before passing through at least one HT evaporator 124a and through at least one LT evaporator 124b in series where the fluid may be further cooled by the HT and/or LT compressors 130a, 130b. The fluid may then return to a reservoir 106.

In a mechanical cooling mode, fluid is cooled only by one or more of the HT and LT compressors 130a, 130b. As illustrated in FIG. 1, at least one valve 109 may control the flow of the glycol solution from a reservoir 106, a fluid pump 103, or another source to where the fluid may be cooled first by at least one HT evaporator 124a and second by at least one LT evaporator 124b in series. From the LT evaporator 124b, the fluid may return to the reservoir 106.

In the partial free cooling and mechanical cooling modes as described herein, a series of water flow may be achieved using a series of one or more air/water heat exchangers (i.e., fluid coolers), followed by at least one higher temperature evaporator, and lastly at least one lower temperature evaporator. No compressor power may be required to reject heat rejected through the air/water heat exchangers. Heat rejected through the higher temperature evaporator(s) requires less compressor power than heat rejected through the lower temperature evaporator(s). This three-step heat rejection process reduces power requirements as compared to conventional cooling systems. Furthermore, a cooling system taking advantage of series water flow as described herein reduces equipment cost as compared to conventional cooling systems. For example, using a cooling system as described herein, two compressors may be used to achieve a similar cooling capacity as using three compressors using conventional cooling systems. However, it should be appreciated, a cooling system as described herein may in some embodiments comprise any number of compressors and any number of evaporators in series water flow arrangement from higher to lower evaporating temperatures.

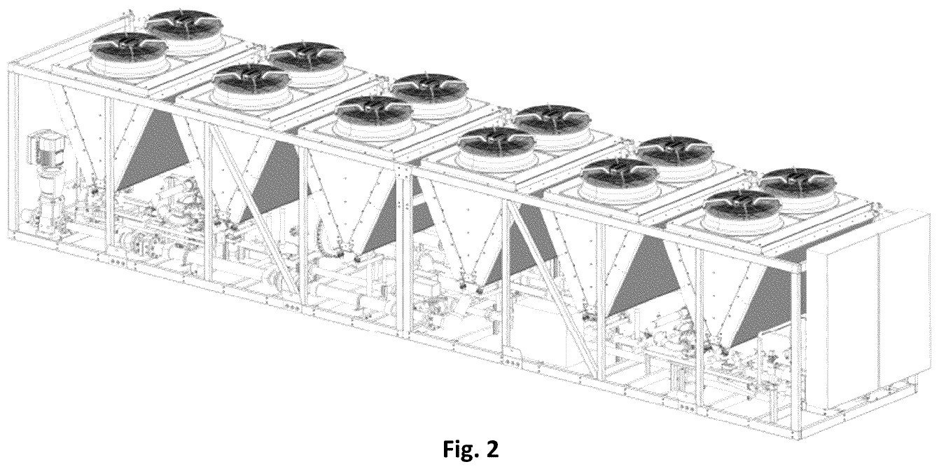

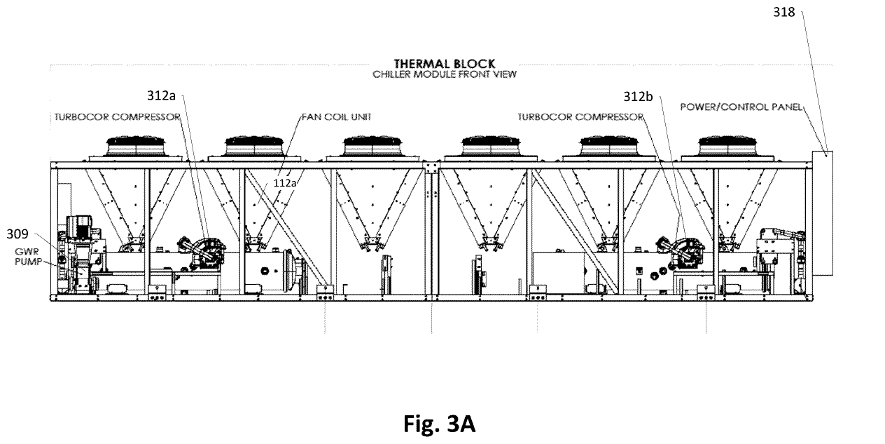

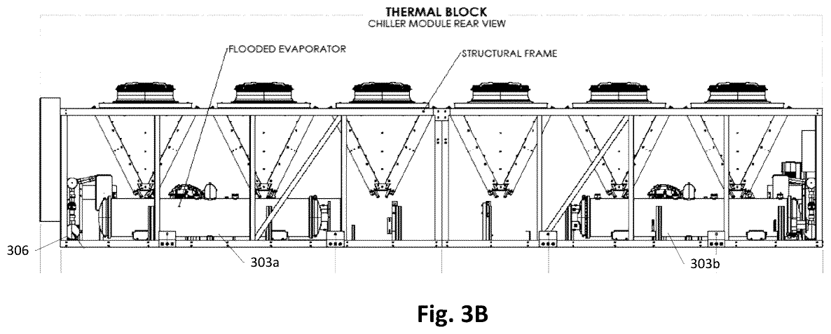

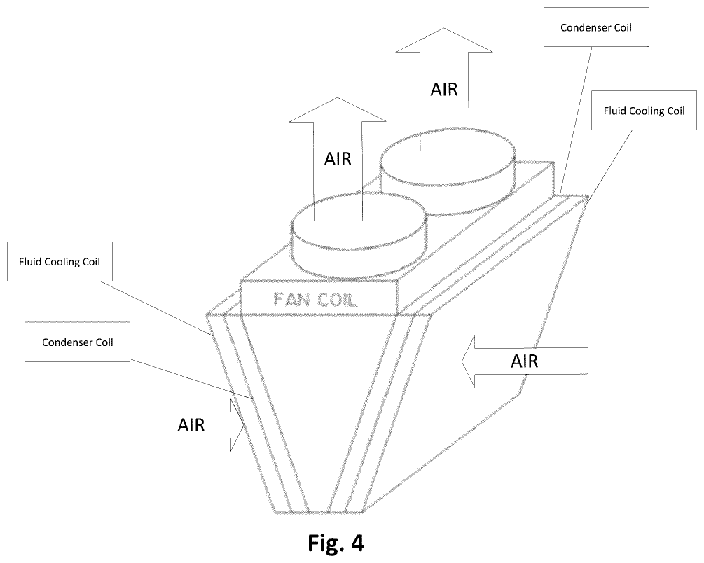

A cooling system as described herein may be as illustrated in FIGS. 2, 3A, and 3B. As illustrated in FIGS. 2, 3A, and 3B, a cooling system may comprise, for example, six pairs of fan units. A fan unit may be as illustrated in FIG. 4. As should be appreciated, air may enter each fan unit first through a fluid cooler heat exchanger coil followed by a condenser heat exchanger coil. Air may exit the fan unit from one or more fan coils.

In the front view of the cooling system as illustrated in FIG. 3A, a glycol water return (GWR) pump 309 can be seen. Also, the cooling system illustrated in FIG. 3A comprises compressors 312a. 312b. The HT circuit of the cooling system comprises a first compressor 312a and the LT circuit of the cooling system comprises a second compressor 312b. A power/control panel 318 can also be seen.

In the rear-view of the cooling system as illustrated in FIG. 3B, the flooded evaporator 303a of the HT circuit and the flooded evaporator 303b of the LT circuit can be seen. A structural frame is used to connect the components of the cooling system into a single block.

As described herein, a cooling system may comprise two refrigerant circuits. A first refrigerant circuit may comprise a first compressor and a higher temperature evaporator and a second refrigerant circuit may comprise a second compressor and a lower temperature evaporator. The higher temperature evaporator and the first compressor may be capable of rejecting a given amount of heat to ambient air using less power than required by the lower temperature evaporator and the second compressor to reject the same amount of heat.

In one or more of the embodiments described herein, the chiller may comprise one or more integrated fluid coolers and/or condenser heat exchangers. Each of the one or more integrated fluid coolers and/or condenser heat exchangers may provide series air flow through first a fluid cooler followed by a condenser. By stacking a fluid cooler and a condenser, an overall footprint required by the chiller may be reduced by roughly half.

In conventional systems, two separate pieces of equipment are required: a fluid cooler (with its own fluid cooling coils and fans) and a chiller (with its own condensing coils and fans). Using a cooling system as described herein on the other hand, only one device is required. Using a cooling system as described herein, a single set of fans enables air flow through both a fluid cooler and a condenser, eliminating the need for at least two separate fans.

A cooling system as described herein operates using both series air flow (through the fluid cooler and condenser) and series water flow (through the HT and LT evaporators). These series air and water flows enable the cooling system to achieve a previously impossible efficiency and relatively low power requirements as compared to conventional cooling systems.

The fluid cooler and condenser heat exchangers may be of an aluminum micro-channel type, which reduces cost, size, and refrigerant charge as compared to conventional systems which typically comprise copper tube aluminum fins.

Because the fluid cooler and condenser use micro-channel coils, the associated pressure drop is low as compared to a copper-tube aluminum fin coils (used by conventional systems), enabling the cooling system to meet efficiency requirements.

A cooling system as described herein may comprise an integrated variable speed water pump. A cooling system including a pump as described herein reduces installation costs as compared to conventional systems.

A cooling system as described herein may comprise a hot gas bypass valve (e.g., a load balancing valve). A cooling system comprising a hot gas bypass valve or load balancing valve as described herein may enable the cooling system to operate below its minimum compressor cooling capacity unlike conventional cooling systems. By keeping the compressor running, a cooling system as described herein may avoid temperature spikes that occur when the compressor is stopped as compared to conventional systems.

The following features may be controlled automatically in such a way as to minimize overall power use of the cooling system: an operating mode selection between free, partial, and mechanical cooling; the number of compressors running, e.g., between zero, one, or two; the loading of the compressors, e.g., between zero and one hundred percent, which may be measured in terms of Watts or percent loading; values associated with the economizers; values associated with the load balancing valve; fan speeds, e.g., between zero and one hundred percent of the design of the fans; etc.

Table 1, below, summarizes an overall control of a cooling system from lower ambient/lower load conditions to higher ambient/higher load conditions as described herein. The goal of the control system may be to select a set of controls for features such as fan speeds, numbers of compressors, economizer settings, etc., based on factors such as cooling load, water flow rate, ambient air temperature, water supply temperature, water return temperature, etc.

In some embodiments, real-time feedback based on results may be used to adjust lookup tables and/or continuous function values in real-time to further reduce input power, optimizing the values based on real-world performance.

Sensors may be used to monitor cooling load, water flow rate, ambient temperature, water supply temperature, water return temperature, etc.

TABLE 1

| | | | LT | HT | Load | | |
|---|---|---|---|---|---|---|---|
| | LT | HT | Economizer | Economizer | Balancing | | |
| Description | Compressor | Compressor | EEV | EEV | Valve | HT Fans | LT Fans |
| Free | Stopped | Stopped | 0% open | 0% open | 0% open | Control glycol supply | |
| Cooling | | | | | | temperature | |
| Min. | Running at | Stopped | 0% open | 0% open | 100% open | Controls LT | Run at a set |
| possible | min | | | | | compressor | speed e.g. |
| compressor | capacity | | | | | pressure | 80% |
| cooling | | | | | | ratio | |
| capacity | | | | | | | |
| Modulate | Running at | Stopped | 0% open | 0% open | Controls | Controls LT | Run at a set |
| load | min | | | | glycol | compressor | speed e.g. |
| balancing | capacity | | | | supply | pressure | 80% |
| valve | | | | | temperature | ratio | |
| Modulate | Running-- | Stopped | 0% open | 0% open | 0% open | Controls LT | Run at a set |
| LT | controls | | | | | compressor | speed e.g. |
| compressor | glycol | | | | | pressure | 80% |
| | supply temp | | | | | ratio | |
| Modulate | Running, | Running, | 0% open | 0% open | 0% open | Controls LT | Controls HT |
| both | controls | capacity is | | | | compressor | compressor |
| compressors | glycol | varied | | | | pressure | pressure |
| | supply temp | between e.g. | | | | ratio | ratio |
| | | 40 to 60% | | | | | |
| | | of LT | | | | | |
| | | compressor | | | | | |
| | | capacity | | | | | |
| Preferred | Running, | Running, | Controls LT | Controls HT | 0% open | Controls LT | Controls HT |
| condition: | controls | capacity is | economizer | economizer | | compressor | compressor |
| Modulate | glycol | varied | superheat | superheat | | pressure | pressure |
| both | supply temp | between e.g. | | | | ratio | ratio |
| compressors | | 40 to 60% | | | | | |
| with | | of LT | | | | | |
| economizers | | compressor | | | | | |
| on | | capacity | | | | | |
| Max | Running at | Running at | Controls LT | Controls HT | 0% open | Controls LT | Controls HT |
| Capacity | max | max | economizer | economizer | | compressor | compressor |
| | capacity | capacity | superheat | superheat | | pressure | pressure |
| | | | | | | ratio | ratio |

In the tables described herein, a zero value indicates the feature is turned off. To minimize the power requirements and to maximize the efficiency, each of the following features may be adjusted as needed: one or more HT economizers, one or more LT economizers, one or more HT compressors, one or more LT compressors, one or more HT fan speeds, one or more LT fan speeds, and/or other features.

A goal of the control scheme may be to minimize the input power (e.g., kW per ton) required by the cooling system. To reduce input power, one or more features of the cooling system may be adjusted or turned off or on. For example, if the load balancing valve is active (i.e., the valve is more than zero percent open) the LT economizer valve may be closed. In some embodiments, a preferred, most efficient, operating condition may be in which both compressors are running with both economizers active. Also, to minimize the overall fan and compressor power usage, the fan speed, and the number of running compressors may be adjusted.

In some embodiments, a controller comprised by the cooling system may store in memory one or more lookup tables. In some embodiments, a controller may instead be capable of using one or more functions, such as an algebraic equation, to determine a setting for each feature. It should be appreciated, a controller may be capable of determining optimum settings using other means, such as by generating and executing a model, using machine learning or AI, or other methods. For example, a controller may store in memory a series of look up tables. In each table, a first arrangement may be associated with ambient temperatures, a second arrangement may be associated with percent load, and a third arrangement may be associated with glycol solution return temperatures. It should be appreciated other arrangement may be used depending on use case scenarios. Each entry in the table(s) may show a fan speed, number of compressors running, and/or other variables for features of the cooling system such that the total power consumed by fans, compressors, and/or other features of the cooling system is minimized. Other variables which may be adjusted include, for example, economizer status, load balancing valve status, etc. For a given set of conditions, e.g., cooling load, ambient temperature, return water temperature, etc., there may be a unique set of outputs which minimizes total input power: HT and LT compressor status, HT and LT compressor loading, HT and LT fan speeds, HT, and LT economizer settings, load balancing valve settings, etc.

As the ambient temperature, the cooling load, and the return water temperature change, the settings can be updated to keep the input power requirement at a minimum using such a lookup table. It should be appreciated that the arrangements of such a lookup table may be at any precision level, such as single digit precision, e.g., 100%, 99%, 98%, etc., for percent load and 40° F., 41° F., 42° F., etc., for ambient temperature. In some embodiments, the precision may be greater or lesser, such as ten percent differences, e.g., 100%, 90%, 80%, etc., for percent load and 40° F., 50° F., 60° F., etc., for ambient temperature.

The controller may be capable of using different lookup tables depending on the particular ratio of glycol to water being used for the particular cooling system. The numbers presented in the tables described herein are provided for illustration purposes only and should not be considered as limiting in any way.

In some embodiments, a controller comprised by the cooling system may operate similarly by using continuous functions instead of lookup tables.

Table 2, below, shows an example of power minimization. As shown, the ambient temperature, glycol flow, return glycol temperature and supply glycol temperature are the same for all three operating values. However, the HT and LT fans speed are set to 80, 60, and 100%, respectively. In this example, a minimum chiller power value of 88.44 KW is seen when the fans' speed is 80%. In can be appreciated that finer increments of fan speeds may be used to find a yet lower minimum chiller input power.

Table 2, below, shows an example of power minimization. As shown, the ambient temperature, glycol flow, return glycol temperature and supply glycol temperature are the same for all three operating values. However, the HT and LT fans speed are set to 80, 60, and 100%, respectively. In this example, a minimum chiller power value of 88.44 KW is seen when the fans' speed is 80%. In can be appreciated that although 20% increments of fan speed are shown in Table 2, finer increments or continuous functions of fan speeds may similarly be used to find a yet lower minimum total chiller input power requirements.

In addition to the example shown in Table 2, other values of outputs such as HT and LT compressor status, HT and LT compressor loading, HT and LT fan speeds, HT, and LT economizer settings, load balancing valve settings, etc. may be controlled to minimize power based on specific input values such as ambient temperature, glycol flow, and glycol supply/return temperatures.

It should be appreciated by those skilled in the art that minimum power use for any given operating conditions may be calculated by use of flow and energy balances, heat exchanger performance models, and rating curves and/or tables of individual components such as fans, pumps, and compressors. The information presented herein is not intended to address system optimization in general. Instead, optimization of this chiller's specific configuration as detailed in the claims is addressed.

Minimum power use for a given set of conditions based on said calculated model may be further refined by comparing and adjusting calculated results with measured values based on chiller operating data such as actual flow rate, ambient air temperature, and glycol supply/return temperatures.

TABLE 2

| | | Operating | Operating | Operating |
|---|---|---|---|---|
| Description | Units | Values 1 | Values 2 | Values 3 |
| Ambient Temperature | [F] | 86 | 86 | 86 |
| Glycol Flow | [gpm] | 156 | 156 | 156 |
| Return Glycol | [F] | 97 | 97 | 97 |
| Temperature | | | | |
| Supply Glycol | [F] | 62 | 62 | 62 |
| Temperature | | | | |
| HT Fans Speed | [—] | 0.80 | 0.60 | 1.00 |
| LT Fans Speed | [—] | 0.80 | 0.60 | 1.00 |
| Chiller Total Power | [KW] | 88.44 | 92.41 | 89.24 |

Implementation Methods

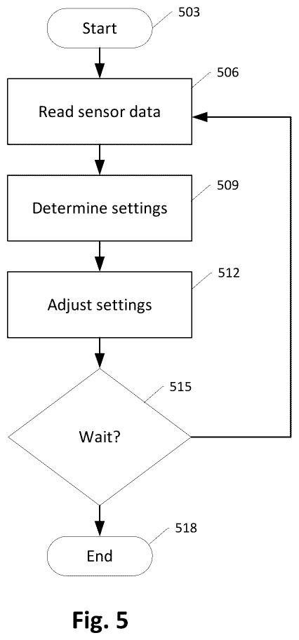

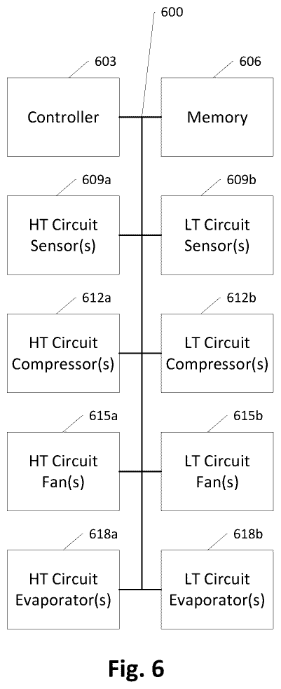

A control method of a cooling system as described herein may in some embodiments comprise reading input paraments, ambient temperature, percent load, return water temperature, and/or other values, looking up fan speeds, number of compressors running, and/or other values based on performance tables, and controlling the cooling system to reach a desired attribute such as minimum power consumption. Such a method may be as illustrated by the flowchart of FIG. 5 and may be implemented using one or more elements of a cooling system such as illustrated in FIG. 6.

In some embodiments, a control method of a cooling system as described herein may comprise reading input paraments and converting the input parameter information to an intermediate parameter such as compressor pressure ratio(s) which in turn may be used to control fan speeds and/or other variables.

In some embodiments, one or more continuous functions associated with ambient temperature, percent load, and water return/supply temperatures may be used as opposed to or in addition to the use of lookup tables.

According to one or more of the embodiments described herein, a method of controlling a cooling system may begin at 503. The method may be performed by a controller 603 of a cooling system as described herein. The controller 603 may be in communication with one or more of memory 606, one or more HT circuit sensors 609a, one or more LT circuit sensors 609b, one or more HT circuit compressors 612a, one or more LT circuit compressors 612b, one or more HT circuit fans 615a, one or more LT circuit fans 615b, one or more HT circuit evaporators 618a, one or more LT circuit evaporators 618b, and/or other HT and LT circuit components of the cooling system via a bus 600 as illustrated in FIG. 6.

At 506, the controller 603 may read sensor data from one or more HT circuit sensors 609a and/or LT circuit sensors 609b. Sensor data may comprise, for example, ambient air temperature, return water or glycol-water solution temperature, cooling system load percentage, and/or other information. In some embodiments, sensor data may be used to calculate statuses such as cooling load percentage. For example, glycol solution pressure and temperature, may be used to determine a flow rate.

At 509, the controller 603 may determine one or more settings of features of the cooling system. Determining the settings may comprise using one or more lookup tables, equations, functions, models, etc., to determine an ideal set of settings for one or more HT circuit compressors 612a, one or more LT circuit compressors 612b, one or more HT circuit fans 615a, one or more LT circuit fans 615b, one or more HT circuit evaporators 618a, one or more LT circuit evaporators 618b, and/or other HT and LT circuit components of the cooling system.

At 512, the controller may adjust one or more settings of features of the cooling system. Adjusting settings of the cooling system may comprise, for example, setting fan speeds, numbers of compressors running, and/or changing other controllable elements. In some embodiments, adjusting settings of the cooling system may comprise changing between one or more of a free cooling mode, a partial free cooling mode, and a mechanical cooling mode.

At 515, the controller may determine whether to continue or wait for a specified time before continuing. For example, if the cooling system is switched off, the method may cease to continue and may end at 518. Under normal operating settings, the method may continue indefinitely. In some embodiments, the method may continue at certain intervals, such as once per second, per hour, etc. If the method is to continue, the method may comprise returning to 506 with the reading of sensor data.

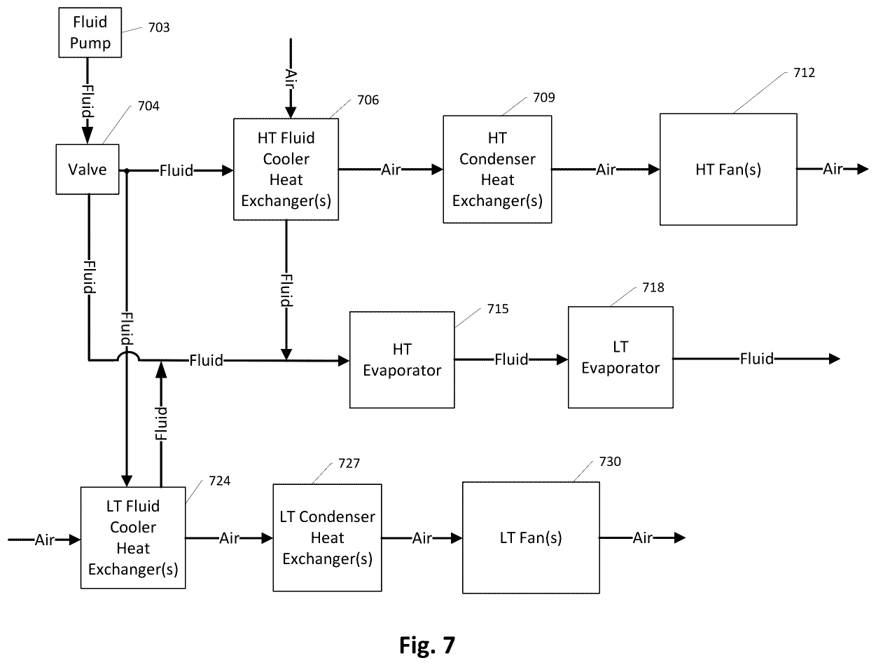

FIG. 7 is a simplified illustration of a cooling system in accordance with one or more of the embodiments described herein which may be controlled using a control system. The control system may execute an engineering model to calculate power input and may be used to measure and/or estimate temperatures, pressures, flow rates, and other variables during operation of the cooling system.

A user may be enabled to interact with the engineering model by setting variables for elements. For example, the user may be enabled to turn off and on HT and/or LT economizers, adjusting glycol-to-water percentages, types of fans, and power levels of fans and pumps. The user may also be enabled to input or control a fluid flowrate. It should be appreciated any other settings may similarly be adjusted. Based on the settings, the model may be capable of showing system performance for a cooling system as described herein.

As illustrated in FIG. 7, a cooling system may include a number of controllable elements. For example, the cooling system may include a fluid pump 703, a valve 704, HT fluid cooler heat exchanger(s) 706, HT condenser heat exchanger(s) 709, HT fan(s) 712, an HT evaporator 715, an LT evaporator 718, LT fluid cooler heat exchanger(s) 724, LT condenser heat exchanger(s) 727, and LT fan(s) 730. Each of the controllable elements of the cooling system may be monitored and/or controlled. For example, sensors may be used to monitor temperatures and/or flowrates of fluid and/or air throughout the cooling system. Each of the elements of the cooling system may be adjusted to allow for fine-tuning of the cooling system. Control systems, which may include PLCs (Programmable Logic Controllers), sensors, and actuators, may be used to automate such adjustments based on real-time data and predetermined setpoints.

In a cooling system, various control variables can be adjusted to optimize performance, efficiency, and meet the desired cooling load. Here are the key components and their associated control variables:

Adjusting these variables allows for fine-tuning of the cooling system, ensuring it meets the cooling demands efficiently. Control systems, which may include PLCs (Programmable Logic Controllers), sensors, and actuators, are often used to automate these adjustments based on real-time data and predetermined setpoints.

The fluid pump 703 may be controllable by managing a flow rate. For example, adjusting a speed of the fluid pump 703 may be used to control the flow rate of the fluid 733 output by the fluid pump 703.

In some implementations, sensors may be used to monitor flowrate, temperature, pressure, and/or other variables relating to the fluid 733 output by the fluid pump 703.

The valve 704 may be controllable by managing a valve position. For example, adjusting a position of the valve can regulate or direct the flow of fluid 733 output by the fluid pump 703. The valve 704 may, for example, control whether the fluid 733 output by the fluid pump 703 flows to first fluid heat exchangers 706 and then the HT evaporator 715 or bypasses the fluid cooler heat exchangers and flows directly to the HT evaporator.

The HT fluid cooler heat exchanger(s) 706 and/or the LT fluid cooler heat exchanger(s) 724 may be controllable in such a way as to regulate a fluid flow rate, an air flow rate, a temperature differential, and/or other variables. For example, regulating the flow rate can adjust the amount of heat being removed from the system. By controlling fan speed, the rate at which air moves through the HT and LT fluid cooler heat exchanger(s) 706, 724 can be adjusted, affecting heat exchange efficiency. Monitoring and adjusting the temperature differential can optimize heat transfer rates.

The HT evaporator 715 and/or the LT evaporator 718 may be controllable in such a way as to control a refrigerant or fluid flow rate and/or temperature of gas leaving the evaporator. For example, evaporators 715, 718 may include one or more controllable valves which may be used to adjust flow rates.

The HT condenser heat exchanger(s) 709 and LT condenser heat exchanger(s) 727 may be controllable in such a way as to control a refrigerant flow rate, an air flow rate, a temperature differential, and/or other variables. For example, regulating the flow rate can adjust the amount of heat being removed from the system. By controlling fan speed, the rate at which air moves through the HT and LT condenser heat exchanger(s) 709, 727 can be adjusted, affecting heat exchange efficiency.

The HT and LT fans 712, 730 may be controllable in such a way as to control variable speeds to adjust airflow and/or direction to maintain desired temperatures and/or airflow rates over the heat exchangers.

Other components not shown, such as compressors, economizers, etc., as illustrated in FIG. 1 may also be controlled and/or monitored. Any of the components of a cooling system as described herein may be automatically controlled by a control system to turn the components on and off and to adjust variables such as flow rates and temperatures.

Users may be enabled to adjust settings to minimize power usage for a cooling system in accordance with one or more of the embodiments described herein. Such settings may include a number of options based on different ambient temperatures. For example, for different ambient temperatures (e.g., 40, 50, 60, 70, 80 degrees Fahrenheit), users may be enabled to control one or more of a flow rate of fluid (e.g., gallons per minute of glycol solution), HT fan speeds, LT fan speeds, and power to one or more of HT evaporators, LT evaporators, HT cooling elements, LT cooling elements, HT compressor(s), and LT compressor(s), for example. In some implementations, settings may be adjusted for different temperature levels at various step changes (e.g., every ten degrees or finer) and/or continuous functions may be used to yield lower values of kW per ton at each condition.

In the foregoing description, for the purposes of illustration, methods were described in a particular order. It should be appreciated that in alternate embodiments, the methods may be performed in a different order than that described without departing from the scope of the embodiments. It should also be appreciated that the methods described above may be performed as algorithms executed by hardware components (e.g., circuitry) purpose-built to carry out one or more algorithms or portions thereof described herein. In another embodiment, the hardware component may comprise a general-purpose microprocessor (e.g., CPU, GPU) that is first converted to a special-purpose microprocessor. The special-purpose microprocessor then having had loaded therein encoded signals causing the, now special-purpose, microprocessor to maintain machine-readable instructions to enable the microprocessor to read and execute the machine-readable set of instructions derived from the algorithms and/or other instructions described herein. The machine-readable instructions utilized to execute the algorithm(s), or portions thereof, are not unlimited but utilize a finite set of instructions known to the microprocessor. The machine-readable instructions may be encoded in the microprocessor as signals or values in signal-producing components and included, in one or more embodiments, voltages in memory circuits, configuration of switching circuits, and/or by selective use of particular logic gate circuits. Additionally, or in the alternative, the machine-readable instructions may be accessible to the microprocessor and encoded in a media or device as magnetic fields, voltage values, charge values, reflective/non-reflective portions, and/or physical indicia.

Embodiments of the present disclosure include a cooling system comprising: a first air to fluid heat exchanger; a first refrigerant circuit comprising a first evaporator, a first condenser, and a first compressor; and a second refrigerant circuit comprising a second evaporator, a second condenser, and a second compressor, wherein: the first evaporator is associated with a higher evaporating temperature relative to the second evaporator, a fluid is in a series flow relationship through a fluid cooler heat exchanger followed by the first evaporator and followed by the second evaporator, and air is in a series flow through the fluid cooler heat exchanger followed by both the first and second condensers.

Aspects of the cooling system include wherein the first and second refrigerant circuits each further comprise an integrated fluid cooling and condenser heat exchanger.

Aspects of the cooling system include wherein the cooling system further comprises aluminum micro-channel type air, water, and condenser heat exchangers.

Aspects of the cooling system include wherein the cooling system further comprises an integrated variable speed water pump.

Aspects of the cooling system include wherein a fan draws the air through both the fluid cooler heat exchanger and the first and second condensers.

Embodiments of the present disclosure also include a method of operating a cooling system, the cooling system comprising: at least one air to fluid heat exchangers; a first refrigerant circuit comprising at least one first evaporator, condenser and a first compressor; and a second refrigerant circuit comprising at least one second evaporator condenser and a second compressor, wherein the first evaporator is associated with a higher evaporating temperature relative to the second evaporator, wherein a working fluid such as water is in a series flow relationship through first the fluid cooler heat exchanger followed by the higher temperature evaporator and lastly by the lower temperature evaporator, and wherein ambient air flow is in a series relationship through first the fluid cooler heat exchanger followed by both first and second refrigeration circuit condensers the method comprising: reading of various inputs such as glycol/water flow rate, percent loading, and ambient air temperature; using continuous functions and/or lookup tables to determine an operating configuration that minimizes overall input power; and setting outputs such as compressor(s) running status, condenser fan(s) speed(s) and others to values such that the minimal overall power use is achieved.

Aspects of the method include wherein the cooling system further comprises aluminum micro-channel type air, water, and condenser heat exchangers.

Aspects of the method include wherein the cooling system further comprises an integrated variable speed water pump(s).

Aspects of the method include wherein a fan draws the air through both the fluid cooler heat exchanger and the condenser heat exchanger.

Embodiments also include a control system for controlling a cooling system, the cooling system comprising: at least one air to fluid heat exchangers; a first refrigerant circuit comprising at least one first evaporator, condenser, and compressor; and a second refrigerant circuit comprising at least one second evaporator condenser and compressor, wherein the first evaporator is associated with a higher evaporating temperature relative to the second evaporator, and a working fluid such as water is in a series flow relationship through first the fluid cooler heat exchanger followed by the higher temperature evaporator and lastly by the lower temperature evaporator, and further where ambient air flow is in a series relationship through first the fluid cooler heat exchanger followed by both first and second refrigeration circuit condensers, wherein the control system comprises a processor and computer-readable program instructions which, when executed by the processor, cause the processor to: read various inputs such as glycol/water flow rate, percent loading, and ambient air temperature; use continuous functions and/or lookup tables to determine an operating configuration that minimizes overall input power; and set outputs such as compressor(s) running status, condenser fan(s) speed(s) and others to values such that the minimal overall power use is achieved.

Aspects of the control system include wherein the first and second refrigerant circuits each further comprise integrated fluid cooling and condenser heat exchangers with series air flow through first the air/water heat exchanger followed by the condenser.

Aspects of the control system include wherein the cooling system further comprises aluminum micro-channel type air, water, and condenser heat exchangers.

Aspects of the control system include wherein the cooling system further comprises an integrated variable speed water pump.

Aspects of the control system include wherein air enters the cooling system through a fluid cooler heat exchanger and a condenser heat exchanger, wherein the fluid cooler heat exchanger and the condenser heat exchanger are in series.

In another embodiment, the microprocessor further comprises one or more of a single microprocessor, a multi-core processor, a plurality of microprocessors, a distributed processing system (e.g., array(s), blade(s), server farm(s), “cloud”, multi-purpose processor array(s), cluster(s), etc.) and/or may be co-located with a microprocessor performing other processing operations. Any one or more microprocessors may be integrated into a single processing appliance (e.g., computer, server, blade, etc.) or located entirely or in part in a discrete component connected via a communications link (e.g., bus, network, backplane, etc. or a plurality thereof).

Examples of general-purpose microprocessors may comprise, a central processing unit (CPU) with data values encoded in an instruction register (or other circuitry maintaining instructions) or data values comprising memory locations, which in turn comprise values utilized as instructions. The memory locations may further comprise a memory location that is external to the CPU. Such CPU-external components may be embodied as one or more of a field-programmable gate array (FPGA), read-only memory (ROM), programmable read-only memory (PROM), erasable programmable read-only memory (EPROM), random access memory (RAM), bus-accessible storage, network-accessible storage, etc.

Such machine-executable instructions may be stored on one or more machine-readable mediums, such as CD-ROMs or other type of optical disks, floppy diskettes, ROMs, RAMS, EPROMS, EEPROMs, magnetic or optical cards, flash memory, or other types of machine-readable mediums suitable for storing electronic instructions. Alternatively, the methods may be performed by a combination of hardware and software.

In another embodiment, a microprocessor may be a system or collection of processing hardware components, such as a microprocessor on a client device and a microprocessor on a server, a collection of devices with their respective microprocessor, or a shared or remote processing service (e.g., “cloud” based microprocessor). A system of microprocessors may comprise task-specific allocation of processing tasks and/or shared or distributed processing tasks. In yet another embodiment, a microprocessor may execute software to provide the services to emulate a different microprocessor or microprocessors. As a result, first microprocessor, comprised of a first set of hardware components, may virtually provide the services of a second microprocessor whereby the hardware associated with the first microprocessor may operate using an instruction set associated with the second microprocessor.

While machine-executable instructions may be stored and executed locally to a particular machine (e.g., personal computer, mobile computing device, laptop, etc.), it should be appreciated that the storage of data and/or instructions and/or the execution of at least a portion of the instructions may be provided via connectivity to a remote data storage and/or processing device or collection of devices, commonly known as “the cloud,” but may include a public, private, dedicated, shared and/or other service bureau, computing service, and/or “server farm.”

Examples of the microprocessors as described herein may include, but are not limited to, at least one of Qualcomm® Snapdragon® 800 and 801, Qualcomm® Snapdragon® 610 and 615 with 4G LTE Integration and 64-bit computing, Apple® A7 microprocessor with 64-bit architecture, Apple® M7 motion microprocessors, Samsung® Exynos® series, the Intel® Core™ family of microprocessors, the Intel® Xeon® family of microprocessors, the Intel® Atom™ family of microprocessors, the Intel Itanium® family of microprocessors, Intel® Core® i5-4670K and i7-4770K 22 nm Haswell, Intel® Core i5-3570K 22 nm Ivy Bridge, the AMD® FX™ family of microprocessors, AMD® FX-4300, FX-6300, and FX-8350 32 nm Vishera, AMD® Kaveri microprocessors, Texas Instruments® Jacinto C6000™ automotive infotainment microprocessors, Texas Instruments® OMAP™ automotive-grade mobile microprocessors, ARM® Cortex™-M microprocessors, ARM® Cortex-A and ARM926EJ-S™ microprocessors, other industry-equivalent microprocessors, and may perform computational functions using any known or future-developed standard, instruction set, libraries, and/or architecture.

Any of the steps, functions, and operations discussed herein can be performed continuously and automatically.

The exemplary systems and methods of this invention have been described in relation to cooling systems and components and methods for controlling cooling systems; however, to avoid unnecessarily obscuring the present invention, the preceding description omits a number of known structures and devices. This omission is not to be construed as a limitation of the scope of the claimed invention. Specific details are set forth to provide an understanding of the present invention. It should, however, be appreciated that the present invention may be practiced in a variety of ways beyond the specific detail set forth herein.

While the flowcharts have been discussed and illustrated in relation to a particular sequence of events, it should be appreciated that changes, additions, and omissions to this sequence can occur without materially affecting the operation of the invention.

A number of variations and modifications of the invention can be used. It would be possible to provide for some features of the invention without providing others.

In yet another embodiment, the systems and methods of this invention can be implemented in conjunction with a special purpose computer, a programmed microprocessor or microcontroller and peripheral integrated circuit element(s), an ASIC or other integrated circuit, a digital signal microprocessor, a hard-wired electronic or logic circuit such as discrete element circuit, a programmable logic device or gate array such as PLD, PLA, FPGA, PAL, special purpose computer, any comparable means, or the like. In general, any device(s) or means capable of implementing the methodology illustrated herein can be used to implement the various aspects of this invention. Exemplary hardware that can be used for the present invention includes computers, handheld devices, telephones (e.g., cellular, Internet enabled, digital, analog, hybrids, and others), and other hardware known in the art. Some of these devices include microprocessors (e.g., a single or multiple microprocessors), memory, nonvolatile storage, input devices, and output devices. Furthermore, alternative software implementations including, but not limited to, distributed processing or component/object distributed processing, parallel processing, or virtual machine processing can also be constructed to implement the methods described herein as provided by one or more processing components.

In yet another embodiment, the disclosed methods may be partially implemented in software that can be stored on a storage medium, executed on programmed general-purpose computer with the cooperation of a controller and memory, a special purpose computer, a microprocessor, or the like. In these instances, the systems and methods of this invention can be implemented as a program embedded on a personal computer such as an applet, JAVA® or CGI script, as a resource residing on a server or computer workstation, as a routine embedded in a dedicated measurement system, system component, or the like. The system can also be implemented by physically incorporating the system and/or method into a software and/or hardware system.

Embodiments herein comprising software are executed, or stored for subsequent execution, by one or more microprocessors and are executed as executable code. The executable code being selected to execute instructions that comprise the particular embodiment. The instructions executed being a constrained set of instructions selected from the discrete set of native instructions understood by the microprocessor and, prior to execution, committed to microprocessor-accessible memory. In another embodiment, human-readable “source code” software, prior to execution by the one or more microprocessors, is first converted to system software to comprise a platform (e.g., computer, microprocessor, database, etc.) specific set of instructions selected from the platform's native instruction set.

Although the present invention describes components and functions implemented in the embodiments with reference to particular standards and protocols, the invention is not limited to such standards and protocols. Other similar standards and protocols not mentioned herein are in existence and are considered to be included in the present invention. Moreover, the standards and protocols mentioned herein, and other similar standards and protocols not mentioned herein are periodically superseded by faster or more effective equivalents having essentially the same functions. Such replacement standards and protocols having the same functions are considered equivalents included in the present invention.

The present invention, in various embodiments, configurations, and aspects, includes components, methods, processes, systems and/or apparatus substantially as depicted and described herein, including various embodiments, sub combinations, and subsets thereof. Those of skill in the art will understand how to make and use the present invention after understanding the present disclosure. The present invention, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the invention has been presented for purposes of illustration and description. The foregoing is not intended to limit the invention to the form or forms disclosed herein. In the foregoing Detailed Description for example, various features of the invention are grouped together in one or more embodiments, configurations, or aspects for the purpose of streamlining the disclosure. The features of the embodiments, configurations, or aspects of the invention may be combined in alternate embodiments, configurations, or aspects other than those discussed above. This method of disclosure is not to be interpreted as reflecting an intention that the claimed invention requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the invention.

Moreover, though the description of the invention has included description of one or more embodiments, configurations, or aspects and certain variations and modifications, other variations, combinations, and modifications are within the scope of the invention, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

The disclosure has been described with reference to the preferred embodiments. Modifications and alterations will occur to others upon a reading and understanding of the preceding detailed description. It is intended that the disclosure be construed as including all such modifications and alterations as far as they come within the scope of the appended claims or the equivalents thereof.

A number of variations and modifications of the disclosures can be used. As should be appreciated, it would be possible to provide for some features of the disclosures without providing others.

The present disclosure, in various embodiments, includes components, methods, processes, systems and/or apparatus substantially as depicted and described herein, including various embodiments, sub-combinations, and subsets thereof. Those of skill in the art will understand how to make and use the present disclosure after understanding the present disclosure. The present disclosure, in various embodiments, includes providing devices and processes in the absence of items not depicted and/or described herein or in various embodiments hereof, including in the absence of such items as may have been used in previous devices or processes, for example for improving performance, achieving ease and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments for the purpose of streamlining the disclosure. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment. Thus, the following claims are hereby incorporated into this Detailed Description, with each claim standing on its own as a separate preferred embodiment of the disclosure.

Moreover, though the description of the disclosure has included description of one or more embodiments and certain variations and modifications, other variations and modifications are within the scope of the disclosure, e.g., as may be within the skill and knowledge of those in the art, after understanding the present disclosure. It is intended to obtain rights which include alternative embodiments to the extent permitted, including alternate, interchangeable and/or equivalent structures, functions, ranges, or steps to those claimed, whether or not such alternate, interchangeable and/or equivalent structures, functions, ranges or steps are disclosed herein, and without intending to publicly dedicate any patentable subject matter.

What is claimed is:

1. A cooling system comprising:
a first air to fluid heat exchanger;
a first refrigerant circuit comprising a first evaporator, a first condenser, and a first compressor; and
a second refrigerant circuit comprising a second evaporator, a second condenser, and a second compressor, wherein:
the first evaporator is associated with a higher evaporating temperature relative to the second evaporator,
a fluid is in a series flow relationship through a fluid cooler heat exchanger followed by the first evaporator and followed by the second evaporator, and
air is in a series flow through the fluid cooler heat exchanger followed by both the first and second condensers.

2. The cooling system of claim 1, wherein the first and second refrigerant circuits each further comprise an integrated fluid cooling and condenser heat exchanger.

3. The cooling system of claim 1, further comprising aluminum micro-channel type air, water, and condenser heat exchangers.

4. The cooling system of claim 1, further comprising an integrated variable speed water pump.

5. The cooling system of claim 1, wherein a fan draws the air through both the fluid cooler heat exchanger and the first and second condensers.

6. A method of operating a cooling system, the cooling system comprising:
at least one air to fluid heat exchangers;
a first refrigerant circuit comprising at least one first evaporator, condenser and a first compressor; and
a second refrigerant circuit comprising at least one second evaporator condenser and a second compressor,
wherein the first evaporator is associated with a higher evaporating temperature relative to the second evaporator,
wherein a working fluid such as water is in a series flow relationship through first the fluid cooler heat exchanger followed by the higher temperature evaporator and lastly by the lower temperature evaporator, and
wherein ambient air flow is in a series relationship through first the fluid cooler heat exchanger followed by both first and second refrigeration circuit condensers the method comprising:
reading of various inputs such as glycol/water flow rate, percent loading, and ambient air temperature;
using continuous functions and/or lookup tables to determine an operating configuration that minimizes overall input power; and
setting outputs such as compressor(s) running status, condenser fan(s) speed(s) and others to values such that the minimal overall power use is achieved.

7. The method of claim 6, further comprising aluminum micro-channel type air, water, and condenser heat exchangers.

8. The method of claim 6, further comprising an integrated variable speed water pump(s).

9. The method of claim 6, wherein a fan draws the air through both the fluid cooler heat exchanger and the condenser heat exchanger.

10. A control system for controlling a cooling system, the cooling system comprising:
at least one air to fluid heat exchangers;
a first refrigerant circuit comprising at least one first evaporator, condenser, and compressor; and
a second refrigerant circuit comprising at least one second evaporator condenser and compressor,
wherein the first evaporator is associated with a higher evaporating temperature relative to the second evaporator,
and a working fluid such as water is in a series flow relationship through first the fluid cooler heat exchanger followed by the higher temperature evaporator and lastly by the lower temperature evaporator,
and further where ambient air flow is in a series relationship through first the fluid cooler heat exchanger followed by both first and second refrigeration circuit condensers,
wherein the control system comprises a processor and computer-readable program instructions which, when executed by the processor, cause the processor to:
read various inputs such as glycol/water flow rate, percent loading, and ambient air temperature;
use continuous functions and/or lookup tables to determine an operating configuration that minimizes overall input power; and
set outputs such as compressor(s) running status, condenser fan(s) speed(s) and others to values such that the minimal overall power use is achieved.

11. The control system of claim 10, wherein the first and second refrigerant circuits each further comprise integrated fluid cooling and condenser heat exchangers with series air flow through first the air/water heat exchanger followed by the condenser.

12. The control system of claim 10, wherein the cooling system further comprises aluminum micro-channel type air, water, and condenser heat exchangers.

13. The control system of claim 10, wherein the cooling system further comprises an integrated variable speed water pump.

14. The control system of claim 10, wherein air enters the cooling system through a fluid cooler heat exchanger and a condenser heat exchanger, wherein the fluid cooler heat exchanger and the condenser heat exchanger are in series.
